(19) United States
(12) Patent Application Publication
(10) Pub. No.: US 2025/0034414 A1
(43) Pub. Date: Jan. 30, 2025

(54) INKJET RESIN COMPOSITION AND DISPLAY DEVICE

(71) Applicant: Samsung Display Co., Ltd., Yongin-Si (KR)

(72) Inventors: Jong Sung YOU, Yongin-si (KR); Jeong Woo MOON, Yongin-si (KR)

(21) Appl. No.: 18/443,309

(22) Filed: Feb. 16, 2024

(30) Foreign Application Priority Data
Jul. 25, 2023 (KR) 10-2023-0096709

(51) Int. Cl. C09D 11/104; C09D 11/101; C09D 11/30; H10K 59/80

(52) U.S. Cl. CPC C09D 11/104; C09D 11/101; C09D 11/30; H10K 59/8722

(57) ABSTRACT

An inkjet resin composition according to an embodiment includes 16% to 24% by weight of a urethane oligomer, 56% to 84% by weight of a monomer, 4% to 6% by weight of a crosslinking agent, 4% to 6% by weight of an additive, and 1% to 3% by weight of a photo-initiator, and the content of the semi-crystalline polymer in the urethane oligomer is 5% to 50% by weight.

### CROSS-REFERENCE TO RELATED APPLICATION

This application claims priority to and the benefit of Korean Patent Application No. 10-2023-0096709 filed in the Korean Intellectual Property Office on Jul. 25, 2023, the entire contents of which are incorporated herein by reference.

### BACKGROUND

### (a) Field of the Inventive Concept

The present disclosure relates to an inkjet resin composition and a display device using the inkjet resin composition.

### (b) Description of the Related Art

As information technology develops, the importance of a display device as a connection medium between a user and information is being highlighted.

Recently, research and development of a foldable display device, a bendable display device, a rollable display device, etc., using the advantage of a flexible display panel that can be bent or folded, is being conducted.

Such display devices may be applied to various fields such as televisions and monitors as well as portable electronic devices and wearable devices.

Recently, portable electronic devices such as smart phones and tablet PCs are becoming lighter and thinner for ease of portability and various researches are ongoing in various fields for ease of use.

In particular, a “foldable” electronic device with a flexible display provides a relatively larger screen than a general bar-type electronic device, but when the electronic device is folded, the size is reduced, making it convenient to carry. Therefore, it is in the limelight as an electronic device to satisfy consumers' taste.

In the case of such a foldable display device, it is necessary to secure reliability in a folding or bending operation of each member used.

In addition, an adhesive resin used to form an adhesive layer applied to display devices of various shapes is required to have stability with respect to components of display devices of various shapes.

### SUMMARY

Embodiments are meant to provide an inkjet resin composition with improved impact resistance and a display device including the inkjet resin composition.

An inkjet resin composition according to an embodiment includes 16% to 24% by weight of a urethane oligomer, 56% to 84% by weight of a monomer, 4% to 6% by weight of a crosslinking agent, 4% to 6% by weight of an additive, and 1% to 3% by weight of a photo-initiator, and the urethane oligomer includes a semi-crystalline polymer and the content of the semi-crystalline polymer in the urethane oligomer is 5% to 50% by weight.

The urethane oligomer may have a molecular weight of 3000 to 6000.

The urethane oligomer may further include an amorphous polymer.

The amorphous polymer may be polyethylene oxide.

The semi-crystalline polymer may include polycaprolactone having a molecular weight of 1000 to 5000.

The semi-crystalline polymer may include at least one selected from the group consisting of polycarbonate, polyethylene terephthalate, polybutylene terephthalate, polyarylate, poly (DPAA), polyether imide, and polyoxymethylene.

The monomer may include 4-hydroxylbutyl acrylate, 2-hydroxyethyl acrylate, tetrahydrofurfuryl acrylate, and exo-1,7,7-trimethylbicyclo [2.2.1] hept-2-yl acrylate.

The additive may include a silane coupling agent, an adhesion promoter, and an anti-yellowing agent.

The photo-initiator may include a short-wavelength initiator cured at a wavelength of 320 nm to 365 nm and a long-wavelength initiator cured at a wavelength of 370 nm to 420 nm.

The inkjet resin composition may have a viscosity of 30 cp or less.

A display device according to an embodiment includes a display panel, a cover window disposed on one surface of the display panel, and an adhesive layer disposed between the display panel and the cover window, wherein the adhesive layer includes a cured inkjet resin composition which is a cured layer of inkjet resin composition, the inkjet resin composition includes 16% to 24% by weight of urethane oligomer, 56% to 84% by weight of monomer, 4% to 6% by weight of crosslinking agent, 4% to 6% by weight additive, and 1% to 3% by weight photo-initiator, and the urethane oligomer includes a semi-crystalline polymer and the content of the semi-crystalline polymer in the urethane oligomer may be 5% to 50% by weight.

An edge of the adhesive layer may have a curved edge.

The urethane oligomer may have a molecular weight of 3000 to 6000.

The urethane oligomer may further include an amorphous polymer.

The amorphous polymer may be polyethylene oxide.

The semi-crystalline polymer may be polycaprolactone having a molecular weight of 1000 to 5000.

The semi-crystalline polymer may include at least one selected from the group consisting of polycarbonate, polyethylene terephthalate, polybutylene terephthalate, polyarylate, poly (DPAA), polyether imide, and polyoxymethylene.

The monomer may include 4-hydroxylbutyl acrylate, 2-hydroxyethyl acrylate, tetrahydrofurfuryl acrylate, and exo-1,7,7-trimethylbicyclo [2.2.1] hept-2-yl acrylate.

The additive may include a silane coupling agent, an adhesion promoter, and an anti-yellowing agent.

The inkjet resin composition may have a viscosity of 30 cp or less.

According to embodiments, an inkjet resin composition with improved impact resistance and a display device including the inkjet resin composition are provided.

### BRIEF DESCRIPTION OF THE DRAWINGS

FIG. 1 schematically illustrates a cross-section of a display device according to an embodiment.

### DETAILED DESCRIPTION OF THE EMBODIMENTS

Hereinafter, various embodiments of the present inventive concept will be described in detail with reference to the accompanying drawing so that those skilled in the art can easily carry out the present inventive concept.

This inventive concept may be embodied in many different forms and is not limited to the embodiments set forth herein.

In order to clearly describe the present inventive concept, parts irrelevant to the description are omitted, and the same reference numerals are assigned to the same or similar components throughout the specification.

In addition, since the size and thickness of each component shown in the drawings are arbitrarily shown for convenience of explanation, the present inventive concept is not necessarily limited to that which is shown.

In the drawing, the thickness is shown enlarged to clearly express the various layers and regions.

And in the drawing, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

In addition, throughout the specification, when reference is made to a “planar image,” it means when the target part is viewed from above, and when reference is made to a “cross-sectional image,” it means when a cross-section of the target part cut vertically is viewed from the side.

Hereinafter, the inkjet resin composition according to the present embodiment and a display device including the same will be described in detail with reference to the drawing.

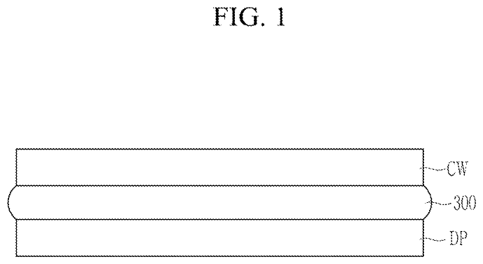

FIG. 1 schematically illustrates a cross-section of a display device according to an embodiment. Referring to FIG. 1, the display device according to the present embodiment includes a display panel DP, a cover window CW disposed on the display panel DP, and an adhesive resin layer 300 disposed between the display panel DP and the cover window CW.

The adhesive resin layer 300 may be formed through UV curing after applying an inkjet resin through an inkjet process.

The adhesive resin layer 300 according to this embodiment may have a curved edge.

This is because the adhesive resin layer 300 is manufactured through coating and curing processes of a liquid forming the adhesive resin layer 300. As shown in FIG. 1, the adhesive resin layer 300 may have a circular are shaped edge in a cross-sectional view.

However, the adhesive resin layer 300 formed by a process other than an inkjet process does not have the circular are shaped edge in a cross-sectional view.

The inkjet resin composition according to the present embodiment may be a composition for forming the adhesive resin layer 300 disposed between the window CW and the display panel DP.

The composition of the inkjet resin composition for forming the adhesive resin layer 300 of FIG. 1 will be described in detail below.

In general, an adhesive resin layer formed by curing an inkjet resin has a brittle property due to a high glass transition temperature, and has a property that is easily broken by external impact is applied.

Therefore, when a cured inkjet resin composition is used to attach the cover window CW to the display panel DP, there may be a problem of cracking of the cured adhesive resin layer 300 due to low impact resistance.

The inkjet resin composition according to this embodiment has an improved impact resistance by ameliorating the property of the inkjet resin composition.

The inkjet resin composition according to the present embodiment may include 16% to 24% by weight of urethane oligomer, 56% to 84% by weight monomer, 4% to 6% by weight crosslinking agent, 4% to 6% by weight additive, and 1% to 3% by weight photo-initiator.

In the inkjet resin composition according to the present embodiment, the urethane oligomer may be urethane acrylate.

The urethane oligomer may have a molecular weight of 3000 to 6000.

The urethane oligomer may contain 5% to 50% by weight of the semi-crystalline polymer.

Also, the urethane oligomer may include an amorphous polymer.

Amorphous polymers may include, for example, polyethylene oxide.

The inkjet resin composition according to the present embodiment is characterized by including a semi-crystalline polymer in the urethane oligomer, and the semi-crystalline polymer may form a partially segmented cross-linked structure by serving as a cross-linking site in the urethane oligomer.

Accordingly, the brittle property of the inkjet resin composition may be ameliorated, and impact resistance may be improved.

That is, the weight of the semi-crystalline polymer may be 5% to 50% by weight based on the total weight of the urethane oligomer.

This content range is a range for the inkjet resin composition to have appropriate strength and low glass transition temperature.

The semi-crystalline polymer may be polycaprolactone having a molecular weight of 1000 to 5000.

Alternatively, the semi-crystalline polymer may be at least one selected from the group consisting of polycarbonate, polyethylene terephthalate (PET), polybutylene terephthalate (PBT), polyarylate (PAR), poly (DPAA), polyether imide (PEI), and polyoxymethylene (POM).

Monomers may include 4-hydroxylbutyl acrylate, 2-hydroxyethyl acrylate, tetrahydrofurfuryl acrylate, and exo-1,7,7-trimethylbicyclo [2.2.1] hept-2-yl acrylate.

The inkjet resin composition according to the present embodiment may include all of the above four types of monomers.

Additives may include silane coupling agents, adhesion promoters, and anti-yellowing agents.

The silane coupling agent is (3-glycidoxypropyl) trimethoxysilane, (3-glycidoxypropyl)triethoxysilane, (3-glycidoxypropyl)methyldimethoxysilane, (3-glycidoxypropyl) seedoxypropyl)methyldiethoxysilane, (3-glycidoxypropyl)dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane phosphorus, 3-triethoxysilyl-N-(1,3 dimethyl-butylidene) propylamine, N-2(aminoethyl)3-aminopropyltrimethoxysilane, N-2 (aminoethyl) 3-aminopropyltriethoxysilane, N-2(aminoethyl) 3-aminopropylmethyldimethoxysilane, N-phenyl-3-aminopropyltrimethoxysilane or (3-isocyanatepropyl)triethoxysilane, etc. These can be used individually or in mixture of 2 or more types.

However, these materials are examples, and the present inventive concept is not limited thereto.

The adhesion promoter may be a silane coupling agent having a reactive substituent such as a carboxyl group, a methacrylic group, an isocyanate group, or an epoxy group.

Specific examples of the silane coupling agent include γ-methacryloxypropyltrimethoxysilane, vinyltriacetoxysilane, vinyltrimethoxysilane, and γ-isocyanatepropyltriethoxysilane. (gamma-isocyanatopropyltriethoxysilane), γ-glycidoxypropyl trimethoxysilane, β-(3,4-epoxy cyclohexylethyltrimethoxysilane) (β-3,4-epoxy cyclo hexylehtyltrimethoxysilane), and the like.

These may be used individually or in combination.

However, these materials are examples, and the present inventive concept is not limited thereto.

The anti-yellowing agent is 3-(2H-benzotriazol-2-yl)-5-(1,1-dimethylethyl) 4-hydroxybenzene linear or branched alkyl esters of 7 to 9 carbon atoms of propanoic acid, 2-(benzotriazol-2-yl)-4-(2,4,4-trimethylpentan-2-yl) phenol, 2-(2′-hydroxy-5′-methylphenyl)benzotriazole, 2-[2′-hydroxy-3′,5′-bis(α,α-dimethylbenzyl)phenyl] benzotriazole, 2-(2′-hydroxy-3′,5′-di-t-butylphenyl)benzotriazole sol, 2,4-hydroxybenzophenone, 2,4-hydroxy-4-methoxybenzophenone, 2,4-hydroxy-4-methoxybenzophenone-5-sulfonic acid, 2,4-diphenyl-6-(2-hydroxy-4-methoxyphenyl)-1,3,5-triazine, 2,4-diphenyl-6-(2-hydroxy-4-ethoxyphenyl)-1,3, 5-triazine, 2,4-diphenyl-6-(2-hydroxy-4-propoxyphenyl)-1,3,5-triazine, or 2,4-diphenyl-6-(2-hydroxy-4-butoxyphenyl)-1,3,5-triazine and the like.

However, these materials are examples, and the present inventive concept is not limited thereto.

The photo-initiator may include a short-wavelength initiator and a long-wavelength initiator, and a short-wavelength initiator and a long-wavelength initiator may be mixed before used.

The short-wavelength initiator may be a material cured at a wavelength of 320 nm to 365 nm, and the long-wavelength initiator may be a material cured at a wavelength of 370 nm to 420 nm.

When an inkjet resin composition is used for forming an adhesive resin layer 300 for a display device, it is possible to form the adhesive resin layer 300 in various shapes such as round/trench/hole shapes, and there is an advantage in that it can be implemented by preparing a coating map.

However, due to the brittle nature of the cured inkjet resin composition, there is a problem in that the cured inkjet resin composition is peeled from the display panel or the resin is broken inside the cured adhesive resin layer.

This is because the number of crosslinking sites between the acrylic oligomer and the short chain of the acrylic monomer increase during curing of the inkjet resin composition.

Therefore, in order to ameliorate the brittle properties of the cured inkjet resin composition, it is necessary to form a partially segmented cross-linked structure.

In this embodiment, the brittle properties of the inkjet resin composition were improved by adding a semi-crystalline polymer capable of serving as a cross-linking site into the urethane oligomer.

The inkjet resin composition according to the present embodiment may have a viscosity of 30 cp or less at room temperature.

The inkjet resin composition having the viscosity of 30 cp or less at room temperature may be easily ejected from an inkjet device.

When the viscosity at room temperature is 30 cp or more, the inkjet resin composition may not be easily ejected from an inkjet device.

Then, the compositions and compositional differences between the inkjet resin composition according to this embodiment (Embodiment 1), the slit resin composition according to other embodiments (Embodiment 2), and the inkjet resin composition according to another embodiment (Embodiment 3) will be described below. The resulting properties will be compared and explained.

Table 1 shows the composition of the inkjet resin composition according to this embodiment (Embodiment 1) and the inkjet resin compositions according to other embodiments (Examples 2 and 3).

The inkjet resin composition of Embodiment 1 includes urethane acrylate oligomer, and the urethane acrylate oligomer contains 50% by weight of semi-crystalline polymer, for example, polycaprolactone, having a molecular weight of 1000 to 5000.

In the case of the composition of Embodiment 1, the oligomer content was reduced compared to Embodiment 2 for low viscosity, and did not include a separate flexible component.

Examples 1 and 3 are inkjet resin compositions for an inkjet process, and Embodiment 2 is a resin composition for a slit process.

TABLE 1

| | Embodiment 1 | | Embodiment 2 | | Embodiment 3 | |
|---|---|---|---|---|---|---|
| Component | type | content | type | content | type | content |
| photo | TPO, IRQ 819 | 10% | 1- | 10% | TPO, | 10% |
| Initiator | | | hydroxycyclohexyl | | Darocur | |
| | | | diamine | | MBF | |
| | | | diisocyanate | | | |
| monomer | 4-hydroxylbutyl | 60-70% | 2-HPMA, 4- | 20-40% | IBOA, | 60-80% |
| | acrylate, 2-hydroxyethyl | | HBA etc. | | 4-HBA, | |
| | acrylate, | | | | 2-EHA etc. | |
| | tetrahydrofurfuryl | | | | | |
| | acrylate, exo-1,7,7- | | | | | |
| | trimethylbicycl | | | | | |
| | [2.2.1] hept-2-yl | | | | | |
| | acrylate | | | | | |
| oligomer | Urethane | 20-30% | Urethane | 20-40% | Acrylate | 10-20% |
| | acrylate (poly- | (50%) | acrylate | | | |
| | caprolactone) | | | | | |
| flexible | — | 0% | Polybutene | 30-60% | — | 0% |
| component | | | | | | |
| cross- | Isophorone | 10% | Isophorone | 10% | Multi- | 10% |
| linker | diaminediisocyanate | | diamine | | functional | |
| | | | diisocyanate | | | |
| additive | other than Silane | 10% | other than | 10% | other than | 10% |
| | CA | | tackifier | | Silane CA | |

The compounds listed in Table 1 are commercially available names or abbreviations, and their specific meanings are as follows.

TPO is 2,4,6-trimethylbenzoyldiphenyl phosphine oxide.

IRQ 819 is bis(2,4,6-trimethylbenzoyl)-phenylphosphineoxide.

Darocur MBF is methylbenzoylformate.

2-HPMA means 2-hydroxypropyl methacrylate, 4-HBA means 4-hydroxybutyl acrylate, IBOA means isobornyl acrylate, and 2-EHA means 2-ethylhexyl acrylate.

Table 2 below shows the measured physical properties of the compositions of Examples 1 to 3 according to the composition of Table 1 above.

TABLE 2

| | | | | | | Measurement |
|---|---|---|---|---|---|---|
| | | unit | Embodiment 1 | Embodiment 2 | Embodiment 3 | method |
| before | viscosity 25° C. | mPa · s | 19 | 8,200 ± 500 | 30 | Haake |
| hardening | | (cp) | | | | |
| | refractive index | — | 1.46 | 1.481 | 1.493 | Abbe refractometer |
| | liquid density | g/cc | 0.97 | 0.93 | 0.96 | density measurement |
| after | UV | % | 4.5 | 3.2 | 8.0 | system |
| hardening | curing shrinkage | | | | | |
| | rate | | | | | |
| | storage | MPa | 0.24 | 0.21 | 0.87 | rheometer |
| | elasticity rate (G′, | | | | | |
| | 25° C.) | | | | | |
| | Tg (° C.) | ° C. | 3.4 | −19 | 16 | TMA |
| | hardness | Shore | 27 | 20 | 32 | durometer |
| | | A | | | | |
| | elongation | % | 500 | 210 | 215 | UTM |

In Table 1 and Table 2, the viscosity was analyzed using a viscometer.

The composition of each example was analyzed for components and functional groups by FT-IR and PY-GC Mass, and molecular weight and molecular weight distribution of oligomers were analyzed using GPC.

In addition, a storage elasticity rate (viscoelasticity) was analyzed using a rheometer, and mechanical strength (hardness) was analyzed using a durometer (DMA, a dynamic mechanical analyzer).

The glass transition temperature Tg was analyzed using differential scanning calorimetry (DSC) or a Thermomechanical analyzer TMA).

Referring to Table 2, in the case of Embodiment 1 in which polycaprolactone, which is a semi-crystalline polymer, was included in urethane acrylate monomer, the viscosity was lower than that of the compositions of Examples 2 and 3.

Accordingly, it was confirmed that the inkjet process can be easily performed.

In addition, since the glass transition temperature of the composition of Embodiment 1 was the lowest, it was confirmed that the brittle property was ameliorated compared to other compositions.

Therefore, it was confirmed that the composition of Embodiment 1 had greater resistant to impact than other compositions.

In addition, the composition of Embodiment 1 showed a low storage elasticity rate of 0.24 at 25° C. and a high elongation of 500%, indicating that the inkjet resin composition according to Embodiment 1 had high elasticity and elongation.

Therefore, it was confirmed that Embodiment 1 was not easily broken by impact.

Hereinafter, the effect of the inkjet resin composition according to the present embodiment will be described through a specific dynamic impact strength evaluation test example.

### Experimental Embodiment 1: Evaluation of Dynamic Impact Strength

To evaluate the dynamic impact strength, 30 g of four monomers (4-hydroxylbutyl acrylate, 2-hydroxyethyl acrylate, Tetrahydrofurfuryl acrylate, exo-1,7,7-trimethylbicycl [2.2.1] hept-2-yl acrylate) was put into a 3-neck glass reaction vessel equipped with a thermometer and a dropping funnel, and maintained under a nitrogen atmosphere.

The temperature of the reactor was raised to 45° C. to 50° C., and 30 g of urethane acrylate oligomer, 20 g of flexible polymer binder, and 10 g of semi-crystalline polymer binder were added to the reactor.

While stirring the reactor, 3 parts per hundred rubber (phr) of photo-initiator was slowly added.

When the photo-initiator was dissociated after stirring for 1 hour, an additive and a silane coupling agent were added and stirred.

For dynamic impact strength evaluation, a 32 g steel ball with a diameter of 2 mm was used.

The display panel to which the inkjet resin composition was applied and cured was fixed, and the drop height of the ball was measured while changing from 1 cm to 50 cm, and the height at which bubbles were generated was recorded.

Table 3 below shows the results of the dynamic impact strength test performed on the composition.

Ball drop was performed 20 times for each of the four parts of the display panel.

TABLE 3

| | Composition of Embodiment 1 | | | | |
|---|---|---|---|---|---|
| | position (based | upper | upper | bottom | bottom |
| Resin | on the front) | left | right | left | right |
| summary | MIN | 50.0 | 50.0 | 50.0 | 50.0 |
| | B10 | 50.0 | 50.0 | 50.0 | 50.0 |
| | AVG | 50.0 | 50.0 | 50.0 | 50.0 |
| | St dev | 0.0 | 0.0 | 0.0 | 0.0 |
| same | #1 | 50 | 50 | 50 | 50 |
| impact | #2 | 50 | 50 | 50 | 50 |
| [cm] | #3 | 50 | 50 | 50 | 50 |
| | #4 | 50 | 50 | 50 | 50 |
| | #5 | 50 | 50 | 50 | 50 |
| | #6 | 50 | 50 | 50 | 50 |
| | #7 | 50 | 50 | 50 | 50 |
| | #8 | 50 | 50 | 50 | 50 |
| | #9 | 50 | 50 | 50 | 50 |
| | #10 | 50 | 50 | 50 | 50 |
| | #11 | 50 | 50 | 50 | 50 |
| | #12 | 50 | 50 | 50 | 50 |
| | #13 | 50 | 50 | 50 | 50 |
| | #14 | 50 | 50 | 50 | 50 |
| | #15 | 50 | 50 | 50 | 50 |
| | #16 | 50 | 50 | 50 | 50 |
| | #17 | 50 | 50 | 50 | 50 |
| | #18 | 50 | 50 | 50 | 50 |
| | #19 | 50 | 50 | 50 | 50 |
| | #20 | 50 | 50 | 50 | 50 |

Referring to Table 3, it was confirmed that the composition according to this embodiment did not generate bubbles at a drop height of 50 cm during a ball drop test.

Table 4 below shows the result of performing the same dynamic impact strength test on the composition of Embodiment 3.

TABLE 4

| | Composition of Embodiment 3 | | | | |
|---|---|---|---|---|---|
| | position (based | upper | upper | bottom | bottom |
| Resin | on the front) | left | right | left | right |
| summary | MIN | 2.0 | 2.5 | 3.0 | 2.5 |
| | B10 | 2.5 | 3.5 | 3.5 | 3.0 |
| | AVG | 6.6 | 7.8 | 8.9 | 7.7 |
| | St dev | 4.2 | 4.0 | 10.3 | 4.8 |
| same | #1 | 12.5 | 13.5 | 12 | 14.5 |
| impact | #2 | 11 | 8 | 13.5 | 3 |
| [cm] | #3 | 7.5 | 14.5 | 4 | 6.5 |
| | #4 | 14 | 8 | 4 | 7 |
| | #5 | 7.5 | 14.5 | 3.5 | 5 |
| | #6 | 9.5 | 12 | 4 | 13.5 |
| | #7 | 13 | 10 | 12.5 | 13.5 |
| | #8 | 12 | 7.5 | 6 | 14 |
| | #9 | 12.5 | 11 | 12.5 | 6 |
| | #10 | 10 | 8 | 14 | 9.5 |
| | #11 | 3 | 3.5 | 3.5 | 2.5 |
| | #12 | 3.5 | 5.5 | 3 | 3.5 |
| | #13 | 4 | 5.5 | 3.5 | 9 |
| | #14 | 4 | 3.5 | 3.5 | 2.5 |
| | #15 | 2.5 | 3.5 | 3.5 | 3.5 |
| | #16 | 2 | 3 | 3.5 | 3.5 |
| | #17 | 3 | 2.5 | 3.5 | 3.5 |
| | #18 | 2.5 | 3.5 | 3 | 3.5 |
| | #19 | 4 | 10.5 | 10.5 | 16 |
| | #20 | 10.5 | 8.5 | 12.5 | 13 |

In Table 4, the average height at which bubbles start to occur in the ball drop test was 6 cm to 9 cm, which was significantly lower than 50 cm in Table 3.

That is, it was confirmed that the inkjet resin composition according to the present embodiment including the semi-crystalline polymer in the urethane oligomer had higher impact resistance than the inkjet resin composition without the semi-crystalline polymer.

Although the embodiments of the present inventive concept have been described in detail above, the scope of the present inventive concept is not limited thereto, and various modifications and improvements made by those skilled in the art using the basic concepts of the present inventive concept defined in the following claims are also included in the scope of the present inventive concept.

What is claimed is:

1. An inkjet resin composition, comprising:
16% to 24% by weight of a urethane oligomer;
56% to 84% by weight of a monomer;
4% to 6% by weight of a crosslinking agent;
4% to 6% by weight of additives; and
1% to 3% by weight of a photo-initiator;
wherein the urethane oligomer includes a semi-crystalline polymer and content of the semi-crystalline polymer in the urethane oligomer is 5% to 50% by weight.

2. The inkjet resin composition of claim 1, wherein:
the urethane oligomer has a molecular weight of 3000 to 6000.

3. The inkjet resin composition of claim 1, wherein:
the urethane oligomer further comprises an amorphous polymer.

4. The inkjet resin composition of claim 3, wherein:
the amorphous polymer is polyethylene oxide.

5. The inkjet resin composition of claim 1, wherein:
the semi-crystalline polymer comprises polycaprolactone having a molecular weight of 1000 to 5000.

6. The inkjet resin composition of claim 1, wherein:
the semi-crystalline polymer comprises at least one selected from the group consisting of polycarbonate, polyethylene terephthalate, polybutylene terephthalate, polyarylate, poly (DPAA), polyether imide, and polyoxymethylene.

7. The inkjet resin composition of claim 1, wherein:
the monomers comprise 4-hydroxylbutyl acrylate, 2-hydroxyethyl acrylate, tetrahydrofurfuryl acrylate and exo-1,7,7-Trimethylbicyclo [2.2.1] hept-2-yl acrylate.

8. The inkjet resin composition of claim 1, wherein:
the additive includes a silane coupling agent, an adhesion promoter, and an anti-yellowing agent.

9. The inkjet resin composition of claim 1, wherein:
the photo-initiator includes a short wavelength initiator cured at a wavelength of 320 nm to 365 nm and a long wavelength initiator cured at a wavelength of 370 nm to 420 nm.

10. The inkjet resin composition of claim 1, wherein:
the viscosity of the inkjet resin composition is 30 cp or less.

11. A display device, comprising:
a display panel;
a cover window positioned on one side of the display panel; and
an adhesive layer disposed between the display panel and the cover window;
wherein the adhesive layer includes a cured inkjet resin composition which is a cured layer of inkjet resin composition,
wherein the inkjet resin composition comprises:
16% to 24% by weight of a urethane oligomer,
56% to 84% by weight monomer,
4% to 6% by weight of a crosslinking agent,
4% to 6% by weight of additives, and
1% to 3% by weight of a photo-initiator, and
wherein the urethane oligomer includes a semi-crystalline polymer and content of the semi-crystalline polymer in the urethane oligomer is 5% to 50% by weight.

12. The display device of claim 11, wherein:
the adhesive layer has a curved edge.

13. The display device of claim 11, wherein:
the urethane oligomer has a molecular weight of 3000 to 6000.

14. The display device of claim 11, wherein:
the urethane oligomer further comprises an amorphous polymer.

15. The display device of claim 14, wherein:
the amorphous polymer is a polyethylene oxide.

16. The display device of claim 11, wherein:
the semi-crystalline polymer includes polycaprolactone having a molecular weight of 1000 to 5000.

17. The display device of claim 11, wherein:
the semi-crystalline polymer includes at least one selected from the group consisting of polycarbonate, polyethylene terephthalate, polybutylene terephthalate, polyarylate, poly (DPAA), polyether imide, and polyoxymethylene.

18. The display device of claim 11, wherein:
the monomer includes 4-hydroxylbutyl acrylate, 2-hydroxyethyl acrylate, tetrahydrofurfuryl acrylate, and exo-1,7,7-trimethylbicyclo [2.2.1] hept-2-yl acrylate.

19. The display device of claim 11, wherein:
the additive includes a silane coupling agent, an adhesion promoter, and an anti-yellowing agent.

20. The display device of claim 11, wherein:
the inkjet resin composition has a viscosity of 30 cp or less.
